(19) United States
(12) Patent Application Publication
(10) Pub. No.: US 2026/0305300 A1
(43) Pub. Date: Oct. 1, 2026

(54) METHOD FOR MANUFACTURING A SYSTEM-ON-CHIP INCLUDING QUANTUM DOT REGIONS AND MOS TRANSISTORS

(71) Applicant: STMicroelectronics International N.V., Geneva (CH)

(72) Inventor: Carlos Augusto SUAREZ SEGOVIA, Seyssinet-Pariset (FR)

(73) Assignee: STMicroelectronics International N.V., Geneva (CH)

(21) Appl. No.: 19/563,849

(22) Filed: Mar. 11, 2026

(30) Foreign Application Priority Data
Mar. 31, 2025 (FR) FR2503304

(51) Int. Cl. H10W 20/42; H10D 86/00; H10W 20/00

(52) U.S. Cl. CPC H10W 20/422; H10D 86/201; H10W 20/056; H10W 20/077

(57) ABSTRACT

Gate structures are manufactured over a semiconductor layer in a first circuit part adapted to locate regions of quantum dots and in a second circuit part for transistors. A first stop layer is formed in the first circuit part but not the second circuit part. A second stop layer is formed in the first circuit part and in the second circuit part. Metal contacts are formed that vertically pass through the second stop layer and stop at an end located in or on the first stop layer in the first circuit part, and that vertically pass through the second stop layer and stop at an end located in or on the gate structures in the second circuit part.

### PRIORITY CLAIM

This application claims the priority benefit of French Application for Patent No. FR2503304, filed on Mar. 31, 2025, the content of which is hereby incorporated by reference in its entirety to the maximum extent allowable by law.

### TECHNICAL FIELD

Embodiments and implementations relate to electronic circuits usually called “Quantum systems-on-chip”, including an array of quantum bits (or “Qubits”) and a CMOS-type electronic circuit.

### BACKGROUND

CMOS circuits (i.e., digital circuits fitted with Complementary Metal-Oxide-Semiconductor transistors) conventionally include metal contacts electrically connected to the gate regions and to the conduction regions (also referred to as: source/drain regions).

The quantum bit arrays may include gate structures homologous to those of the CMOS circuits, provided to generate quantum dots; as well as metal contacts comparable to those of the CMOS circuits, which are not electrically connected to the gate regions, and which are used to produce a field effect between the quantum dots, for example in order to perform transfers or exchanges of electric charges.

In a quantum system-on-chip technology, the gate structures can be obtained in co-integration (i.e., by common manufacturing steps) between the CMOS circuit and the quantum bit array.

However, the co-integration of the metal contacts presents difficulties, in particular because the co-integrated metal contacts should be designed on the one hand to make contact on the gate regions and the source/drain reservoirs of the MOS transistors, but on the other hand to not to make contact on the gate structures of the quantum bits.

In practice, solely positioning the metal contacts away from the gate structures in the quantum bit array is too risky in the face of the possible variations in the alignments, especially if the manufacture of the contacts is specifically designed to reach the gate structures in the CMOS circuit.

Thus, a quantum system-on-chip technology provides for two distinct manufacturing operations for metal contacts in the CMOS circuit and metal contacts in the quantum bit array.

This is disadvantageous in terms of optimization of manufacturing methods and production costs.

Furthermore, in a quantum system-on-chip technology, the operation of the CMOS circuits may be improved by means of a layer of a material introducing a mechanical stress, such as a tensile stress in the direction of the transistor channel.

However, this stress is not necessarily adapted well to the operation of quantum bits.

Thus, there is a need for optimizing the manufacturing processes of quantum systems-on-chip, and improvements to the operations of the CMOS circuit and of the quantum bit array.

In this regard, there is a need in the art to make it possible to modify and adapt the stress in the part of the quantum bit array, and simultaneously make it possible to produce the metal contacts in co-integration in the quantum bit array and in the CMOS circuit, and also to achieve both optimization of the CMOS circuit and optimization of the quantum bit array.

### SUMMARY

In an embodiment, an additional layer of a material introducing an additional mechanical stress is provided which makes it possible to modify and adapt the stress in the part of the quantum bit array while simultaneously making it possible to produce the metal contacts in co-integration in the quantum bit array and in the CMOS circuit.

According to one aspect, a system-on-chip includes: a first circuit part including regions of quantum dots located in a semiconductor layer facing gate structures, the gate structures being covered by a stack of a first stop layer and a second stop layer, where metal contacts vertically pass through the second stop layer and stop at an end located in or on the first stop layer; and a second circuit part including transistors provided with gate structures, the gate structures being covered by the second stop layer, where metal contacts vertically pass through the second stop layer and stop at an end located in or on the gate structures.

The quantum dots can, for example, be gate structures on a semiconductor region, configured to be able to generate a containment of a single charge (e.g., an electron), for example in the semiconductor region facing a gate structure.

According to one embodiment, the first stop layer is configured to generate a first stress, for example in compression, in a first direction, and the second stop layer is configured to generate a second stress, for example tensile, in the first direction.

According to one embodiment, the gate structures comprise, in the first circuit part, a hard mask layer defining a delimitation of the metal silicide films, and wherein the first stop layer covers the hard mask layer and is aligned on said delimitation.

According to one embodiment, the first circuit part further includes reading metal contacts stopping at an end located in or on the gate structures.

For example, in particular, the reading metal contacts stop at an end located in or on the metal silicide films, in particular in the gate structures located beyond the boundary delimitation of the first stop layer.

According to one embodiment, the metal contacts pass through vertically, for example in addition to a typical pre-metal dielectric layer, the entire thickness of the second stop layer, and stop at said end located in or on a surface portion of the underlying region, the surface portion having a thickness less than 10% of the thickness of the second stop layer.

According to one embodiment, the thickness of the first stop layer is between 10 nm and 100 nm; and the thickness of the second stop layer is between 10 nm and 100 nm.

According to one embodiment, the gate structures are disposed on a semiconductor film of a semiconductor-on-insulator substrate.

According to one embodiment, the gate structures in the first circuit part are arranged in a matrix array of quantum dots; and the gate structures in the second circuit part are arranged in a control electronic circuit.

According to another aspect, a method for manufacturing system-on-chip is proposed comprising: manufacturing, in a first circuit part, gate structures on a semiconductor layer including regions of quantum dots facing the gate structures, and in a second circuit part, transistor gate structures; forming a first stop layer covering the gate structures in the first circuit part; forming a second stop layer covering the first stop layer in the first circuit part and the gate structures in the second circuit part; forming first metal contacts vertically passing through the second stop layer and stopping at an end located in or on the first stop layer in the first circuit part, and forming second metal contacts vertically passing through the second stop layer and stopping at an end located in or on the gate structures in the second circuit part.

According to one implementation, the formation of the first stop layer is configured to generate a first stress, for example in compression, in a first direction, and the second stop layer is configured to generate a second stress, for example tensile, in the first direction.

According to one implementation, the manufacture of the gate structures comprises, in the first circuit part, etching, defined by a first temporary mask, a hard mask layer to delimit a formation of metal silicide films, and wherein formation of the first stop layer comprises forming a first dielectric layer covering the first circuit part and the second circuit part, and etching the first dielectric layer defined by a second temporary mask having the same delimitation as the first temporary mask.

According to one implementation, forming the metal contacts in the first circuit part includes forming reading metal contacts stopping at an end located in or on the gate structures, for example in or on the metal silicide films in particular in the gate structures located beyond the delimitation of the first stop layer.

According to one implementation, forming the metal contacts comprises etching vertical trenches in a pre-metal dielectric volume, wherein etching is performed for a duration resulting in a detection of reaching the second stop layer, and extended by a duration provided to remove the entire thickness of the second stop layer and no further than a surface portion of the underlying region having a thickness less than 10% of the thickness of the second stop layer, and then filling the trenches with metal material.

According to one implementation, the formation of the first stop layer produces a thickness between 10 nm and 100 nm; and the formation of the second stop layer produces a thickness between 10 nm and 100 nm.

According to one implementation, the gate structures are disposed on a semiconductor film of a semiconductor-on-insulator substrate.

According to one implementation, manufacturing the gate structures in the first circuit part is arranged in a matrix array of quantum dots; and manufacturing the gate structures in the second circuit part is arranged in a control electronic circuit.

### BRIEF DESCRIPTION OF THE DRAWINGS

Further advantages and features of the invention will become apparent upon examining the detailed description of non-limiting embodiments and implementations, and from the accompanying drawings, wherein figures:

FIG. 1 schematically illustrates a semiconductor device following a common manufacture of gate structures in a first circuit part and gate structures in a second circuit part;

FIG. 2 schematically illustrates the result of a step of forming a first stop layer covering the gate structures of the first circuit part and the second circuit part;

FIG. 3 schematically illustrates the result of an etching step to form the first stop layer;

FIG. 4 schematically illustrates a step of forming a second stop layer over the first circuit part and the second circuit part;

FIG. 5 schematically illustrates the result of a step of forming the semiconductor device;

FIG. 6 schematically illustrates a step of filling trenches with a metal material; and

FIG. 7 schematically illustrates a step of finalizing the semiconductor device forming the quantum system-on-chip.

### DETAILED DESCRIPTION

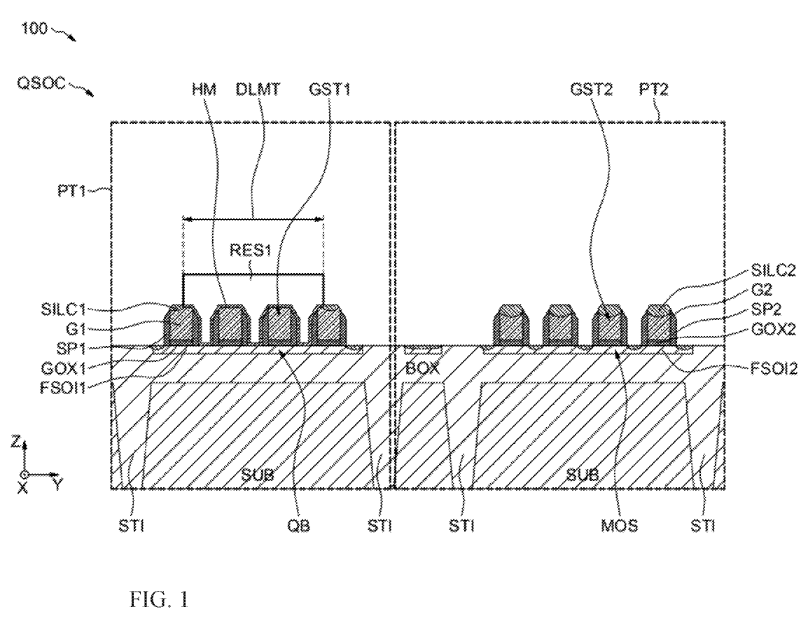

FIGS. 1-7 schematically illustrate a semiconductor device during various steps of a method for manufacturing a so-called “quantum” system-on-chip (QSOC). The views of the figures are shown in cross section in a vertical plane YZ, of an orthogonal reference frame XYZ, where Z is the vertical direction.

The semiconductor device includes a first circuit part PT1 intended to accommodate a circuit forming an array of “quantum dots” (also called “quantum bits”), and a second circuit part PT2 intended to accommodate a CMOS-type electronic circuit.

Quantum dots are structures capable of confining a single electron, in practice at temperatures close to absolute zero, in order, for example, to act on quantum properties of elementary particles, such as state superposition or intrication (for example, in practice relative to the spin of the electron), in order to perform operations on data.

The CMOS electronic circuit is designed, in summary, to control the operations in the quantum dot array, and to transcribe information derived from operations on quantum effects, into usable data.

FIG. 1 thus schematically illustrates the semiconductor device following a common manufacture of gate structures GST1 in the first circuit part PT1 and gate structures GST2 in the second circuit part PT2, starting from a substrate of the semiconductor-on-insulator (SOI) type.

The semiconductor-on-insulator substrate includes a thin semiconductor layer FSOI (also referred to as a “film”) (for example made of doped silicon), disposed on a so-called buried dielectric layer BOX (for example made of silicon oxide) between the semiconductor film FSOI and a carrier substrate SUB (for example made of doped silicon).

Shallow isolation regions STI may be provided in the semiconductor-on-insulator substrate in order to establish lateral electrical isolations in the substrate and the FSOI film.

For example, the semiconductor film FSOI is thin enough (thickness of the film, in the vertical direction Z) so that the semiconductor material is completely devoid of minority charge carriers.

The gate structures GST1, GST2, are thus manufactured in co-integration in the first circuit part PT1 and the second circuit part PT2 starting from the semiconductor thin layer (film) FSOI. The gate structures GST1 (respectively GST2) include a gate conductive region G1 (respectively G2) including for example polycrystalline silicon and metal, resting on a layer of gate oxide GOX1 (respectively GOX2) disposed between the gate conductive region G1 (respectively G2) and the semiconductor film FSOI1 (respectively FSOI2), and framed laterally by dielectric regions of spacers SP1 (respectively SP2) on the flanks of the gate conductive region G1 (respectively G2).

In the first circuit part PT1, the gate structures GST1 are configured to locate regions of quantum dots QB in the semiconductor film FSOI1 opposite the gate structures GST1.

In the second circuit part PT2, the gate structures GST2 are configured and arranged to form transistor gates, referenced MOS, of the “CMOS” type.

Furthermore, starting from the semiconductor device QSOC provided with the gate structures GST1, GST2, the method may comprise a step 100 of forming a hard mask HM, comprising a deposition of a hard-mask dielectric layer, for example made of silicon oxide, over the entire semiconductor device, followed by an etching of this delimited layer DLMT by a first temporary mask RES1.

The first temporary mask RES1 is, for example, obtained by photolithography with a pattern projecting the delimitation DLMT onto the first temporary mask RES1 made of photosensitive resin.

Thus, the dielectric layer of hard mask HM is removed by etching over the entire surface which is not covered by the temporary mask. In particular, the hard mask is not present in the second circuit part PT2.

The etching of the hard mask layer HM may be implemented by wet chemical etching, typically by an acid bath configured to selectively react strongly with the dielectric HM and little with the temporary mask RES1; or by dry physical etching, typically by bombardment of optionally reactive focused ions of the Reactive Ion Etching (RIE) type.

The hard mask HM thus formed makes it possible to delimit a formation of metal silicide films SILC1, SILC2, by a reaction usually referred to as “silicidation” or “salicidation”, which occurs on the silicon surfaces that are not covered by the hard mask HM.

In practice, silicidation is performed after removal of the temporary mask RES1 (the two steps being simultaneously illustrated by concision).

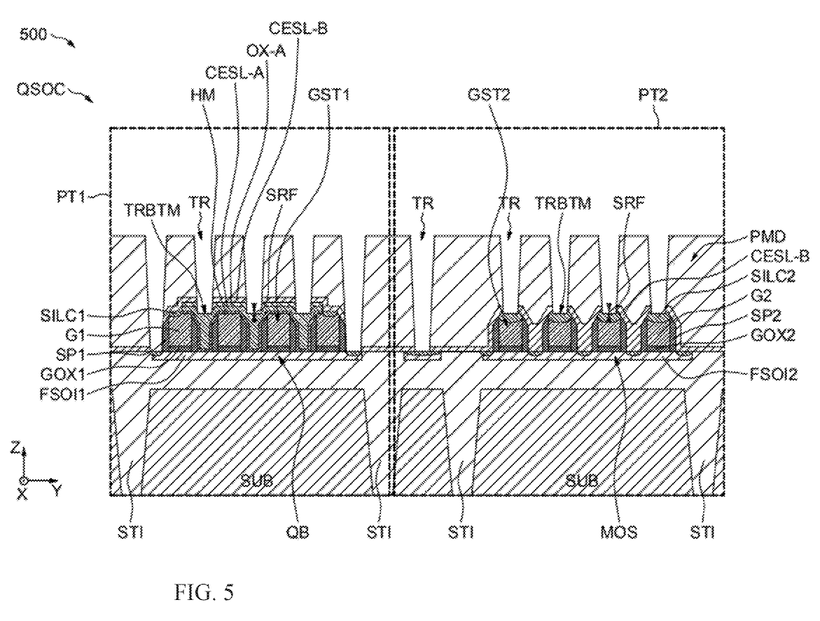

Metal silicon films SILC1, SILC2, in particular on the semiconductor film FSOI1, FSOI2 and on the conductive regions of gate G1, G2, make it possible to establish an ohmic contact (i.e., good electrical conduction) with metal contact pillars CNT (see, for reference, FIGS. 5-7).

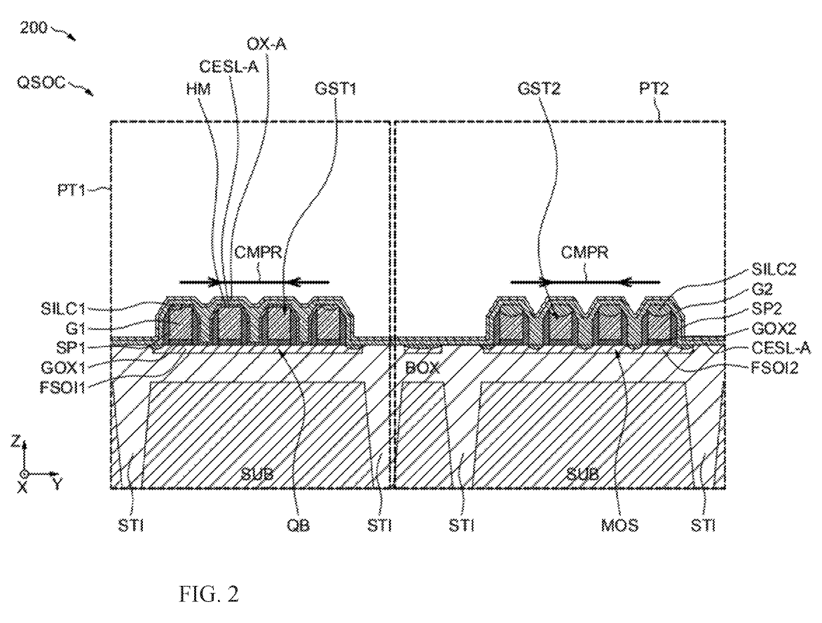

FIG. 2 schematically illustrates the result of a step 200 of forming a first dielectric layer CESL-A (also referred to as a first stop layer), for example made of silicon nitride, covering the first circuit part PT1 and the second circuit part PT2, in particular the gate structures GST.

The first dielectric layer CESL-A is, for example, formed by chemical vapor deposition (CVD), possibly assisted by plasma (PECVD), by physical vapor deposition (PVD), by epitaxy deposition, by atomic layer deposition (ALD) or any other conventional thin film formation technique.

The thickness of the first dielectric layer CESL-A, for example in the vertical direction Z, may be between 10 nm and 100 nm.

An additional dielectric layer OX-A, for example made of silicon oxide, may be formed over the first dielectric layer CESL-A, in step 200.

Advantageously, the first dielectric layer CESL-A is formed so as to generate a first stress CMPR in a first direction Y.

For example, the mechanical stress CMPR in the first silicon nitride stop layer CESL-A can be obtained by conventional techniques of changing the radio frequency (RF) power or deposition pressure or the substrate temperature or precursor flow rate during deposition.

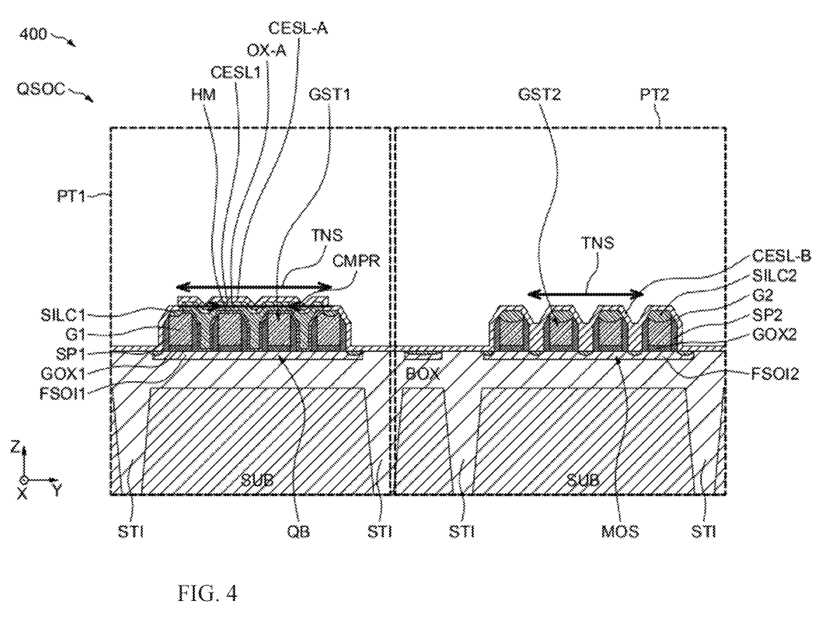

The first stress CMPR is, for example, a compression stress, adapted to oppose a second stress TNS (see, FIG. 4), for example tensile.

Alternatively, the first stress CMPR is, for example, a tensile stress, configured to act in the same direction as a second stress TNS (see, FIG. 4), for example tensile.

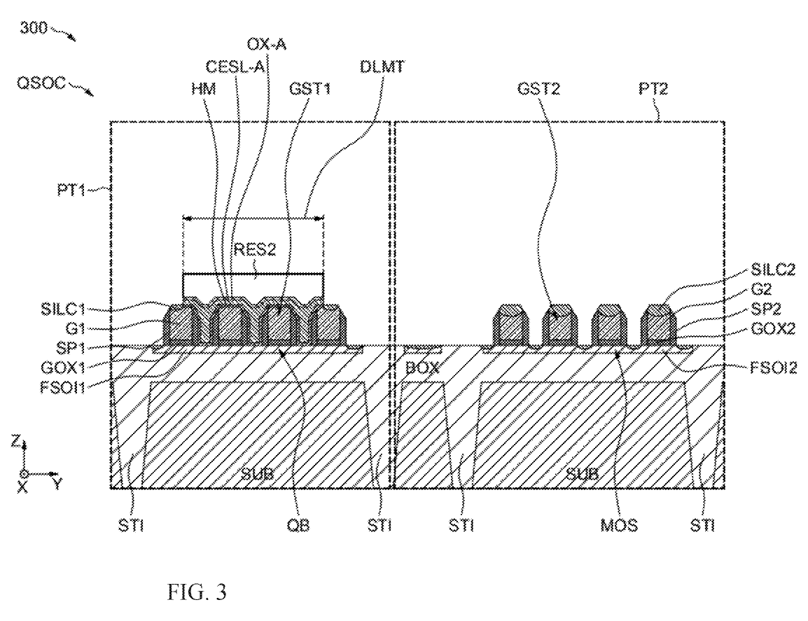

FIG. 3 schematically illustrates the result of an etching step 300 to form the first stop dielectric layer CESL-A.

The etching of the first dielectric layer CESL-A is delimited by a second temporary mask RES2 having the same delimitation DLMT as the first temporary mask RES1.

The second temporary mask RES2 is advantageously obtained by photolithography with the same pattern as the first temporary mask RES1, thus projecting the same delimitation DLMT onto the second temporary mask RES2 made of photosensitive resin.

The first stop dielectric layer CESL-A is removed by etching over the entire surface which is not covered by the second temporary mask RES2.

In particular, the first stop dielectric layer CESL-A is removed throughout the second circuit part PT2.

The etching of the first stop layer CESL-A can be implemented by wet chemical etching, typically an acid bath adapted to selectively react strongly with the dielectric CESL-A and little with the temporary mask RES2; or by dry physical etching, typically by bombardment of optionally reactive focused ions of the Reactive Ion Etching (RIE) type.

Thus, in the first circuit part PT1, the first stop layer CESL-A covers the non-silicided surfaces of the gate structures GST.

The second circuit part PT2 is free from the first stop layer CESL-A, since the first stop layer CESL-A is removed by the etching 300 throughout the second circuit part PT2.

FIG. 4 schematically illustrates a step 400 of forming a second stop layer CESL-B over the first circuit part PT1 and the second circuit part PT2.

The second dielectric layer CESL-B is also formed, for example, by chemical vapor deposition (CVD), possibly assisted by plasma (PECVD), by physical vapor deposition (PVD), by epitaxy deposition, by atomic layer deposition (ALD) or any other conventional thin film formation technique.

The thickness of the second dielectric layer CESL-B, for example taken in the vertical direction Z, may be between 10 and 100 nm.

Thus, the second stop layer CESL-B covers, in particular, the first stop layer CESL-A on the gate structures GST, in the first circuit part PT1; and the second stop layer CESL-B covers in particular the gate structures GST in the second circuit part PT2, in particular the metal silicide films SILC of the conductive regions G.

Advantageously, the formation of the second stop layer CESL-B is configured to generate a second stress TNS in the first direction Y.

For example, the mechanical stress TNS in the second silicon nitride stop layer CESL-B can be obtained by conventional techniques of changing the RF power or deposition pressure or the substrate temperature or precursor flow rate during deposition.

The second stress TNS, for example tensile, is advantageously designed to improve the operation of the MOS transistors of the electronic circuit of the second circuit part PT2.

A tensile stress TNS in the first direction Y advantageously makes it possible to increase the mobility of the charges in the direction of the width of the transistors (i.e., the direction of the channel between the conduction regions of the transistors) and therefore to improve the conduction of the MOS transistors.

However, while the second TNS stress makes it possible to increase the mobility of the charges for the MOS transistors, the same stress TNS is not necessarily optimal for the operation of the quantum dots QB in the first circuit part PT1, and could in the worst case worsen the conditions of the quantum dots QB.

In general, it is desirable for the stress of the matrix of the quantum bits QB in the first circuit part PT1 to be able to be different from the stress of the MOS transistors in the second circuit part PT2.

However, since the formation of the first stop layer CESL-A in the first circuit part PT1, is designed to generate the first stress CMPR in the first direction Y, opposite to the second stress TNS, the resulting sum of the stresses “TNS+CMPR” in the first circuit part PT1 is reduced with respect only to the second stress TNS, possibly null, or even inverse.

Alternatively, if the formation of the first stop layer CESL-A in the first circuit part PT1, is designed to generate the first stress “CMPR” in the first direction Y, in the same direction as the second stress TNS, the resulting sum of the stresses “TNS+CMPR” in the first circuit part PT1 is increased with respect to the second stress TNS alone.

The first stop layer CESL-A is advantageously formed in this respect (steps 200 and 300) specifically to adjust the magnitude (the amount) of the additional mechanical stress CMPR that it generates in the first circuit part PT1, so that the resulting stress TNS+CMPR in the part of the quantum dot array is adapted to the operation of the array.

For example, the sum of the resulting stresses TNS+CMPR may advantageously be configured to generate an optimized or improved mobility of the charges in the semiconductor film FSOI for the quantum dots QB. It should also be noted that the second stop layer CESL-B makes it possible to detect the end of an etching of trenches TR opposite the gate structures GST1, GST2 in the first circuit part PT1 and in the second circuit part PT2, and reference is made in this respect to FIG. 5.

FIG. 5 schematically illustrates the result of a step 500 of forming the semiconductor device QSOC.

After the formation of the first stop layer CESL-A and the second stop layer CESL-B, a volume of pre-metal dielectric PMD, usually silicon oxide, is formed over the first circuit part PT1 and the second circuit part PT2 of the semiconductor device QSOC.

The upper surface of the pre-metal dielectric PMD can be flattened, typically by chemical mechanical polishing (CMP), in order to form a surface of constant height (vertically Z), for example with respect to the semiconductor-on-insulator substrate.

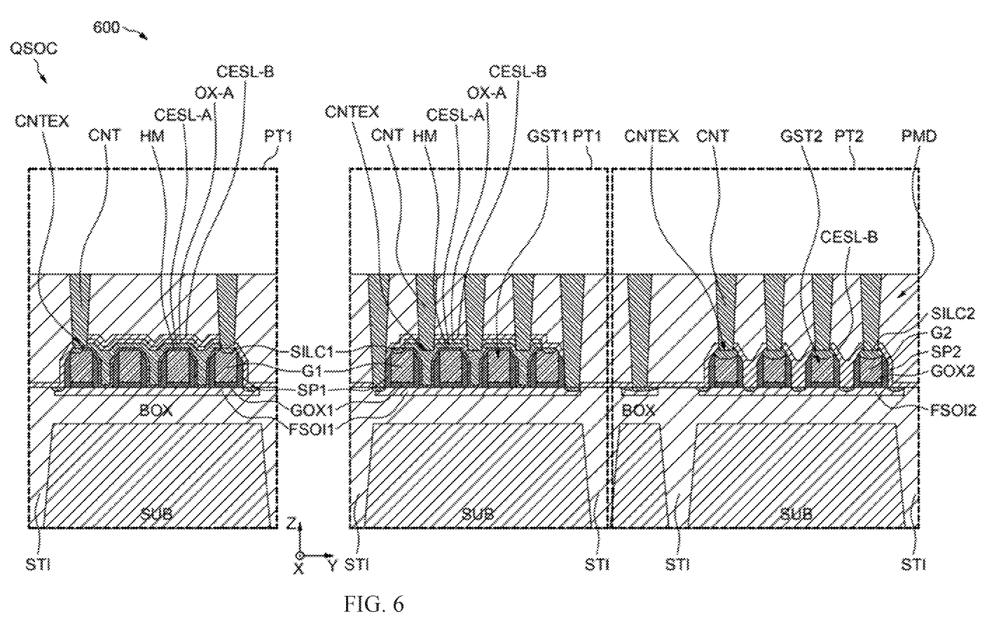

A temporary mask (not shown) is formed on the upper surface of the pre-metal dielectric PMD defining an etching pattern of trenches TR provided for accommodating metal contacts CNT (FIG. 6).

The etching of the vertical trenches TR in the pre-metal dielectric volume PMD is implemented in order to selectively have a high etching dynamic in the dielectric material of the pre-metal volume PMD, and a small etching dynamic in the dielectric materials of the second stop layer CESL-B and of the first stop layer CESL-A (usually made of silicon nitride), and in the silicon of the gate conductive regions G1, G2, and of the semiconductor film FSOI1, FSOI2.

The etching of the trenches TR is a directional (anisotropic) etching directed vertically through the openings of the temporary-mask pattern, usually a reactive ion etching (RIE).

The etching of the trenches TR is implemented until the second stop layer CESL-B is reached.

In this respect, the etching is performed for a sufficient duration to result in a detection of reaching the second stop layer CESL-B.

Indeed, it is possible to detect the moment when the second stop layer CESL-B is reached by the etching, progressing vertically Z from top to bottom, for example by means of an optical control of changing interferometry between the material (oxide) of the pre-metal layer PMD and the material (nitride) of the stop layer CESL-B, or by spectroscopy of the emissions of the species sprayed by the etching.

Furthermore, the etching is extended, after the detection of the second stop layer CESL-B, for a duration sufficient to remove the entire thickness of the second stop layer CESL-B, with an upper margin not greater than 10% of the thickness of the second stop layer CESL-B.

In this respect, it will be possible, for example, to calculate the duration of extension of the etching as a function of the etching dynamics of the material of the stop layer CESL-B and the thickness of the second stop layer CESL-B.

The upper margin and not greater than 10% of the thickness of the second stop layer CESL-B can simply be obtained by applying this margin to the duration of the extension of the etching (i.e., an upper margin not greater than 10% of the duration calculated for etching the thickness of the second stop layer CESL-B).

In practice, since the etching dynamics of the first stop layer CESL-A is identical to that of the second stop layer (and ignoring the etching time of the optional oxide layer OX-A); and since the etching dynamics of the crystalline FSOI1, FSOI2 and polycrystalline G1, G2 silicon layers are even smaller than that of the second etching layer CESL-B; then the bottom of the TRBTM trenches is located in a surface portion SRF of the underlying region which includes CESL-A, FSOI1, FSOI2, G1, G2, which has a thickness less than 10% of the thickness of the second stop layer CESL-B.

FIG. 6 schematically illustrates a step 600 of filling the trenches TR formed in step 500, with a metal material.

For example, filling of the trenches TR with a metal is carried out conventionally by depositing excess metal, in practice tungsten or aluminum for example, then by chemical polishing carried out until the pre-metal dielectric layer is once again uncovered.

Thus, metal contacts CNT are formed in the trenches TR.

In the second portion PT2, the trenches TR are positioned so that the metal contacts CNT, passing vertically through the second stop layer CESL-B, stop at an end CNTEX located in or on the surfaces (e.g., the surface portion SRF) including a metal silicide film SILC2, in particular on the conductive gates G2, the gate structures GST2 and the film FSOI2.

In the first circuit part PT1, the trenches TR are positioned so that the metal contacts CNT, passing vertically through the second stop layer CESL-B, stop at an end CNTEX located in or on (e.g. the surface portion SRF) the first stop layer CESL-A.

Furthermore, in the first circuit part PT1, other trenches TR can be positioned so that the metal contacts CNT, vertically passing through the second stop layer CESL-B, stop at an end CNTEX located in or on the surfaces (e.g., the surface portion SRF) including a metal silicide film SILC1, in particular on the conductive gates G1, the gate structures GST1 and the film FSOI1.

The left-hand view of the first circuit part PT1 in the orientation of FIG. 6, shows schematically a cross-sectional view in a plane YZ at a position of the X axis different from the cross-sectional views described previously. In this position, it can be seen that metal contacts CNT are also designed to establish an electrical connection with the conductive regions G1 of the gate structures in the first circuit part PT1.

In the right-hand view of the first circuit part PT1 in the orientation of FIG. 6, it can be seen that metal contacts CNT are disposed between the neighboring gate structures GST1, and in particular make it possible to produce a field effect between the quantum dots QB, in order for example to carry out transfers or exchanges of charges.

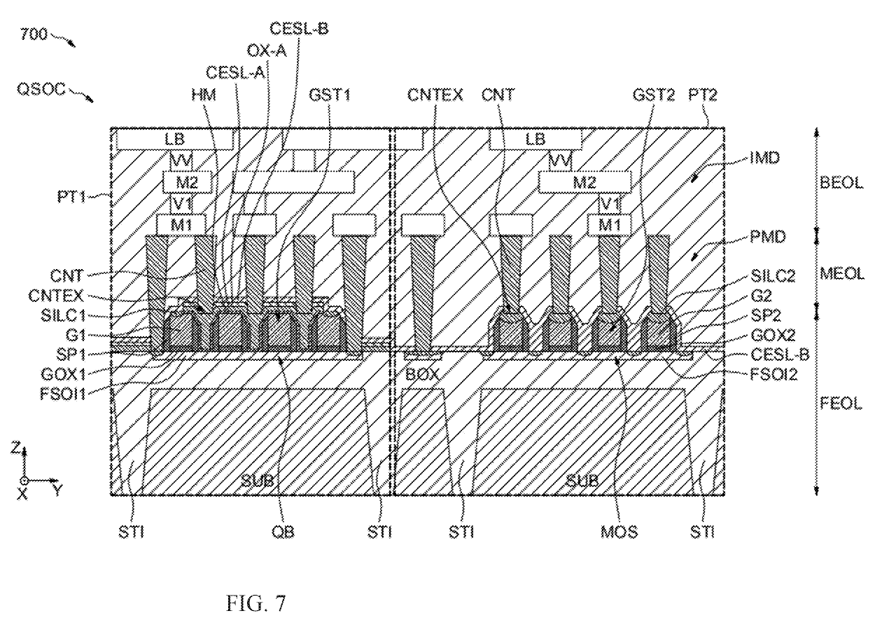

FIG. 7 schematically illustrates a step 700 of finalizing the semiconductor device forming the quantum system-on-chip QSOC.

In step 700, an interconnection region BEOL was formed conventionally, including metal levels M1, M2, LB, separated vertically by inter-metal dielectric layers IMD, and connected by vias V1, VV passing through the inter-metal dielectric layers IMD, in order to construct a circuit interconnecting the semiconductor elements FEOL with each other and with external sockets LB, via the structure MEOL including the metal contacts CNT.

In the quantum system-on-chip thus manufactured, the gate structures GST1 in the first circuit part PT1 are arranged in an array of quantum dots QB; and the gate structures GST2 in the second circuit part PT2 are arranged in a control electronic circuit.

In summary, embodiments and implementations have been described which, by means of an additional layer CESL-A of a material introducing an additional mechanical stress CMPR, make it possible to modify and adapt the stress in the PT1 part of the quantum bit array QB, and simultaneously make it possible to make the metal contacts CNT in co-integration in the quantum bit array PT1 without risking reaching the gate regions GST1, and in the control CMOS circuit PT2.

1. A system-on-chip, including:
a first circuit part including regions of quantum dots located in a semiconductor layer facing first gate structures;
a second circuit part including transistors provided with second gate structures;
wherein the first gate structures are covered by a stack of a first stop layer and a second stop layer;
wherein the second gate structures are covered by the second stop layer but not the first stop layer;
wherein the first stop layer is configured to apply a first stress in a first direction;
wherein the second stop layer is configured to apply a second stress in the first direction;
first metal contacts for the first circuit part that vertically pass through the second stop layer and stop at an end located in or on the first stop layer; and
second metal contacts for the second circuit part that vertically pass through the second stop layer and stopping at an end located in or on the second gate structures.

2. The system-on-chip according to claim 1, wherein one of the first and second stresses is tensile and the other of the first and second stresses is compressive.

3. The system-on-chip according to claim 1, wherein the first gate structures comprise, in the first circuit part, a hard-mask layer defining a delimitation of a metal silicide film, and wherein the first stop layer covers the hard-mask layer and is aligned on said delimitation.

4. The system-on-chip according to claim 1, wherein the first circuit part further includes reading metal contacts stopping at an end located in or on the first gate structures.

5. The system-on-chip according to claim 1, wherein the end located in or on the first stop layer is at a depth less than 10% of a thickness of the second stop layer.

6. The system-on-chip according to claim 1, wherein a thickness of the first stop layer is between 10 nm and 100 nm; and wherein a thickness of the second stop layer is between 10 nm and 100 nm.

7. The system-on-chip according to claim 1, wherein the first and second gate structures are disposed over a semiconductor film of a semiconductor-on-insulator substrate.

8. The system-on-chip according to claim 1, wherein the first gate structures in the first circuit part are arranged in a matrix array of quantum dots; and wherein the second gate structures in the second circuit part are arranged in a control electronic circuit.

9. A method for manufacturing a system-on-chip, comprising:
manufacturing, in a first circuit part, first gate structures over a semiconductor layer configured to locate regions of quantum dots facing the first gate structures;
manufacturing, in a second circuit part, second gate structures of transistors over the semiconductor layer;
forming a first stop layer covering the first gate structures in the first circuit part but not covering the second gate structures in the second circuit part;
forming a second stop layer covering the first stop layer in the first circuit part and covering the second gate structures in the second circuit part;
wherein the first stop layer is configured to apply a first stress in a first direction;
wherein the second stop layer is configured to apply a second stress in the first direction;
forming first metal contacts vertically passing through the second stop layer and stopping at an end located in or on the first stop layer in the first circuit part; and
forming second metal contacts vertically passing through the first stop layer and stopping at an end located in or on the second gate structures in the second circuit part.

10. The manufacturing method according to claim 9, wherein one of the first and second stresses is tensile and the other of the first and second stresses is compressive.

11. The method according to claim 9:
wherein manufacturing the first and second gate structures comprises, in the first circuit part, etching, defined by a first temporary mask, a hard-mask layer to delimit a formation of metal silicide films; and
wherein forming the first stop layer comprises forming a first dielectric layer covering the first circuit part and the second circuit part, then etching the first dielectric layer defined by a second temporary mask having a same delimitation as the first temporary mask.

12. The method according to claim 9, further comprising, in the first circuit part, forming reading metal contacts vertically passing through the first and second stop layers and stopping at an end located in or on the first gate structures.

13. The method according to claim 9, wherein forming the first metal contacts comprises etching vertical trenches in a pre-metal dielectric volume, said etching having a duration resulting in a detection of reaching the second stop layer, and extending etching by a duration provided for removing the entire thickness of the second stop layer and no further than a surface portion of the underlying first stop layer having a thickness less than 10% of the thickness of the second stop layer, and then filling the trenches with a metal material.

14. The method according to claim 9, wherein a thickness of the first stop layer is between 10 nm and 100 nm; and wherein a thickness of the second stop layer is between 10 nm and 100 nm.

15. The method according to claim 9, wherein the first and second gate structures are disposed over a semiconductor film of a semiconductor-on-insulator substrate.

16. The method according to claim 9, wherein manufacturing the first gate structures in the first circuit part is arranged in a quantum dot array; and wherein manufacturing the second gate structures in the second circuit part is arranged in a control electronic circuit.
